(19) United States
(12) Patent Application Publication
(10) Pub. No.: US 2025/0142930 A1
(43) Pub. Date: May 1, 2025

(54) SEMICONDUCTOR APPARATUS AND METHOD OF MANUFACTURING THE SAME

(71) Applicant: INNOSCIENCE (SUZHOU) SEMICONDUCTOR CO., LTD., Jiangsu (CN)

(72) Inventors: Xiao ZHANG, Jiangsu (CN); Jue OUYANG, Jiangsu (CN); Han PENG, Jiangsu (CN); Jianjun ZHOU, Jiangsu (CN)

(73) Assignee: INNOSCIENCE (SUZHOU) SEMICONDUCTOR CO., LTD., Jiangsu (CN)

(21) Appl. No.: 18/681,866

(22) PCT Filed: Oct. 25, 2023
(86) PCT No.: PCT/CN2023/126498

§ 371 Date: Feb. 7, 2024

(30) Foreign Application Priority Data
Dec. 13, 2022 (CN) 202211594560.5

(51) Int. Cl. H10D 64/23; H10D 30/47; H10D 64/00; H10D 64/01; H10D 64/27

(52) U.S. Cl. CPC H10D 64/258; H10D 30/475; H10D 64/01; H10D 64/411; H10D 64/111

(57) ABSTRACT

A semiconductor apparatus and a method of manufacturing the same are provided. A semiconductor apparatus includes a first nitride semiconductor layer, a second nitride semiconductor layer, an electrode, a dielectric structure, a field plate, a plurality of height compensators, and a plurality of vias. The second nitride semiconductor layer is on the first nitride semiconductor layer and has a bandgap greater than that of the first nitride semiconductor layer. The electrode contacts the second nitride semiconductor layer. The dielectric structure is disposed on the second nitride semiconductor layer and covers the electrode. The field plate is in the dielectric structure. The height compensators are in the dielectric structure and are disposed on the electrode and the field plate, respectively. The vias extend into the dielectric structure and contact top surfaces of the height compensators, respectively.

### TECHNICAL FIELD

The present disclosure relates to the field of semiconductor apparatus technology, and more particularly to a semiconductor apparatus including a height compensator and a method of manufacturing the same.

### RELATED ART

Components including direct bandgap semiconductors, for example, semiconductor components including group III-V materials or group III-V compounds (Category: III-V compounds) can operate or work under a variety of conditions or in a variety of environments (e.g., at different voltages and frequencies).

The semiconductor components may include a heterojunction bipolar transistor (HBT), a heterojunction field effect transistor (HFET), a high-electron-mobility transistor (HEMT), a modulation-doped FET (MODFET) and the like.

### SUMMARY OF INVENTION

According to some embodiments of the present disclosure, a semiconductor apparatus includes a first nitride semiconductor layer, a second nitride semiconductor layer, an electrode, a dielectric structure, a field plate, a plurality of height compensators, and a plurality of vias. The second nitride semiconductor layer is on the first nitride semiconductor layer and has a bandgap greater than that of the first nitride semiconductor layer. The electrode contacts the second nitride semiconductor layer. The dielectric structure is disposed on the second nitride semiconductor layer and covers the electrode. The field plate is located in the dielectric structure. The height compensators are located in the dielectric structure and are disposed on the electrode and the field plate, respectively. The vias extend into the dielectric structure and contact top surfaces of the height compensators, respectively.

According to some embodiments of the present disclosure, a method of manufacturing a semiconductor apparatus includes: providing a stacked structure including a first nitride semiconductor layer and a second nitride semiconductor layer formed on the first nitride semiconductor layer, the second nitride semiconductor layer having a bandgap greater than that of the first nitride semiconductor layer; forming an electrode on the second nitride semiconductor layer; forming a first dielectric layer to cover the electrode; forming a field plate on the first dielectric layer; forming a second dielectric layer to cover the field plate; forming a plurality of height compensators penetrating through the second dielectric layer and contacting the electrode and the field plate, respectively; and forming a plurality of vias on the plurality of height compensators.

According to some embodiments of the present disclosure, a semiconductor apparatus includes a first nitride semiconductor layer, a second nitride semiconductor layer, a plurality of electrodes, a dielectric structure, a field plate, and a plurality of via structures. The second nitride semiconductor layer is on the first nitride semiconductor layer and has a bandgap greater than that of the first nitride semiconductor layer. The electrodes contact the second nitride semiconductor layer. The dielectric structure is disposed on the second nitride semiconductor layer and covers the plurality of electrodes. The field plate is located in the dielectric structure. The via structures extend into the dielectric structure and are respectively disposed on the plurality of electrodes. Each of the via structures includes a via portion and a height-compensation portion disposed below the via portion.

The present disclosure provides a semiconductor apparatus and a method of manufacturing the same. The semiconductor apparatus may include height compensators. The height compensators compensate for a height difference (or step difference) between an electrode and a field plate, such that all vias can be in contact with the height compensators at the same height, and be electrically connected with the electrode and the field plate through the height compensators. Moreover, since bottom surfaces of all the vias are at the same height, under-etching or etching-through can be avoided during formation of the vias. In addition, the height compensators can be provided to reduce lengths of the vias, thereby saving the time required for the formation of the vias.

### BRIEF DESCRIPTION OF DRAWINGS

Aspects of the present disclosure may be readily understood from the following detailed description when read in conjunction with the accompanying drawings. It should be noted that various features may not be drawn to scale. Indeed, sizes of various features may be arbitrarily increased or decreased for the sake of clarity of discussion.

FIG. 1 shows a cross-sectional view of a semiconductor apparatus according to some embodiments of the present disclosure.

FIG. 2 shows a cross-sectional view of a semiconductor apparatus according to some embodiments of the present disclosure.

FIG. 3 shows one or more stages of a method of manufacturing a semiconductor apparatus according to some embodiments of the present disclosure.

FIG. 4 shows one or more stages of a method of manufacturing a semiconductor apparatus according to some embodiments of the present disclosure.

FIG. 5 shows one or more stages of a method of manufacturing a semiconductor apparatus according to some embodiments of the present disclosure.

FIG. 6 shows one or more stages of a method of manufacturing a semiconductor apparatus according to some embodiments of the present disclosure.

FIG. 7 shows one or more stages of a method of manufacturing a semiconductor apparatus according to some embodiments of the present disclosure.

FIG. 8 shows one or more stages of a method of manufacturing a semiconductor apparatus according to some embodiments of the present disclosure.

FIG. 9 shows one or more stages of a method of manufacturing a semiconductor apparatus according to some embodiments of the present disclosure.

FIG. 10 shows one or more stages of a method of manufacturing a semiconductor apparatus according to some embodiments of the present disclosure.

FIG. 11 shows one or more stages of a method of manufacturing a semiconductor apparatus according to some embodiments of the present disclosure.

FIG. 12 shows one or more stages of a method of manufacturing a semiconductor apparatus according to some embodiments of the present disclosure.

FIG. 13 shows one or more stages of a method of manufacturing a semiconductor apparatus according to some embodiments of the present disclosure.

FIG. 14 shows one or more stages of a method of manufacturing a semiconductor apparatus according to some embodiments of the present disclosure.

FIG. 15 shows one or more stages of a method of manufacturing a semiconductor apparatus according to some embodiments of the present disclosure.

Common reference numerals are used throughout the accompanying drawings and the detailed description to refer to the same or similar components. The present disclosure will become more apparent from the following detailed description taken in conjunction with the accompanying drawings.

### DESCRIPTION OF EMBODIMENTS

The following disclosure provides many different embodiments or examples for implementing different features of the provided subject matter. Specific examples of components and arrangements are described below. However, these are merely examples and are not intended to be limiting. In the present disclosure, references to forming or disposing a first feature over or on a second feature may encompass embodiments in which the first and second features are formed or disposed to be in direct contact with each other, and may also encompass embodiments in which additional features may be formed or disposed between the first and second features, such that the first and second features may not be in direct contact with each other. In addition, the present disclosure may repeat reference numerals and/or letters in various examples. Such repetition is for purposes of simplicity and clarity and is not intended to limit relationships between various embodiments and/or configurations discussed.

Embodiments of the present disclosure are discussed in detail below. It should be understood, however, that the present disclosure provides many applicable concepts that can be embodied in a wide variety of specific environments. The specific embodiments discussed are illustrative only and do not limit the scope of the present disclosure.

In the related art, there is a height difference (or step difference) between an electrode and a field plate in a semiconductor component, and thus under-etching or etching-through is prone to occur during formation of vias.

In view of this, the present disclosure provides a semiconductor apparatus and a method of manufacturing the same. The semiconductor apparatus may include height compensators. The height compensators compensate for a height difference (or step difference) between an electrode and a field plate, such that all vias can be in contact with the height compensators at the same height, and be electrically connected with the electrode and the field plate through the height compensators. Moreover, since bottom surfaces of all the vias are at the same height, under-etching or etching-through can be avoided during formation of the vias. In addition, the height compensators can be provided to reduce lengths of the vias, thereby saving the time required for the formation of the vias. The semiconductor apparatus according to the present disclosure may be applicable to, but not limited to, HEMT apparatuses, especially low voltage HEMT apparatuses, high voltage HEMT apparatuses, and radio frequency (RF) HEMT apparatuses.

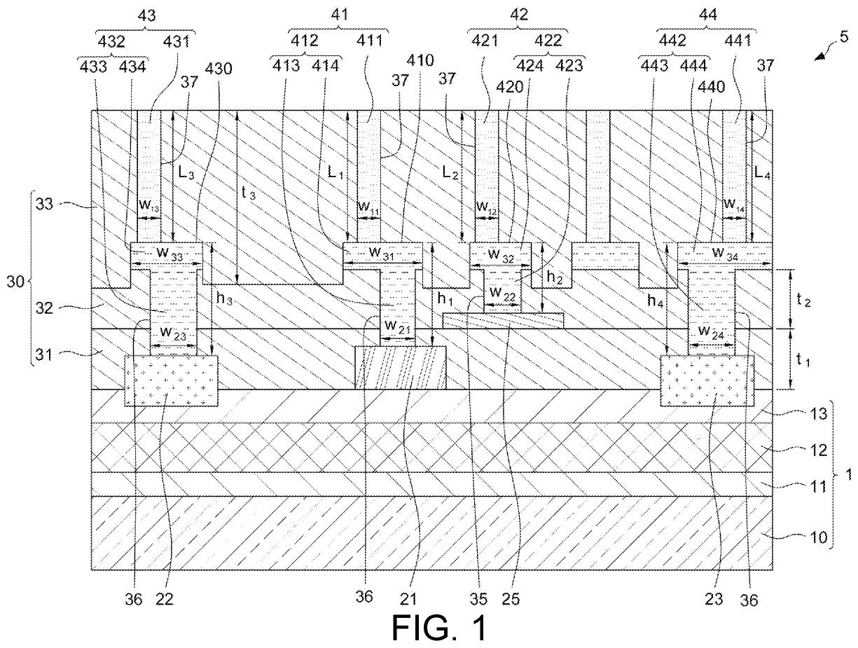

FIG. 1 shows a cross-sectional view of a semiconductor apparatus 5 according to some embodiments of the present disclosure. The semiconductor apparatus 5 may include a base substrate 10, a buffer layer 11, a nitride semiconductor layer 12, a nitride semiconductor layer 13, a plurality of electrodes including, for example, a gate electrode 21, a source electrode 22, and a drain electrode 23, a dielectric structure 30, a field plate 25, a plurality of height compensators including, for example, a height compensator 412, a height compensator 422, a height compensator 432, and a height compensator 442, and a plurality of vias including, for example, a via 411, a via 421, a via 431, and a via 441.

The base substrate 10 may include, but is not limited to, silicon (Si), doped Si, silicon carbide (SiC), silicon germanium (SiGe), gallium arsenide (GaAs), or other semiconductor materials. The base substrate 10 may include, but is not limited to, sapphire, silicon on insulator (SOI), or other suitable materials. A thickness of the base substrate 10 may range from about 200 μm to about 400 μm, e.g., 220 μm. 240 μm, 260 μm, 280 μm, 300 μm, 320 μm, 340 μm, 360 μm, or 380 μm.

The buffer layer 11 may be disposed on the base substrate 10. The buffer layer 11 may be configured to reduce defects caused by lattice mismatch between the base substrate 10 and the nitride semiconductor layer 12.

The nitride semiconductor layer 12 may be disposed on the buffer layer 11. In some embodiments, the nitride semiconductor layer 12 may be referred to as a channel layer. In some embodiments, the nitride semiconductor layer 12 may include a group III-V layer. In some embodiments, the nitride semiconductor layer 12 may include, but is not limited to, a group III nitride, for example, a compound InₐAl_{b}Ga_{1-a-b}N, where a+b≤1. The group III nitride further includes, but is not limited to, for example, a compound AlₐGa₍₁₋ₐ₎N, where a≤1. In some embodiments, the nitride semiconductor layer 12 may include a gallium nitride (GaN) layer. GaN has a bandgap of about 3.4 eV. A thickness of the nitride semiconductor layer 12 may range, but is not limited to, from about 0.1 μm to about 1 μm. In some embodiments, the nitride semiconductor layer 12 may be disposed directly on the base substrate 10.

The nitride semiconductor layer 13 may be disposed on the nitride semiconductor layer 12. In some embodiments, the nitride semiconductor layer 13 may be referred to as a barrier layer. A heterojunction may be formed between the nitride semiconductor layer 13 and the nitride semiconductor layer 12, and polarization of the heterojunction forms a two-dimensional electron gas (2DEG) region in the nitride semiconductor layer 12. In some embodiments, the nitride semiconductor layer 13 may include a group III-V layer. In some embodiments, the nitride semiconductor layer 13 may include, but is not limited to, a group III nitride, for example, a compound InₐAl_{b}Ga_{1-a-b}N, where a+b≤1. The group III nitride may further include, but is not limited to, for example, a compound AlₐGa₍₁₋ₐ₎N, where a≤1. In some embodiments, the nitride semiconductor layer 13 may have a bandgap greater than that of the nitride semiconductor layer 12. In some embodiments, the nitride semiconductor layer 13 may include an aluminum gallium nitride (AlGaN) layer. AlGaN has a bandgap of about 4.0 eV. A thickness of the nitride semiconductor layer 13 may range, but is not limited to, from about 10 nm to about 100 nm.

In some embodiments, the base substrate 10, the buffer layer 11, the nitride semiconductor layer 12, and the nitride semiconductor layer 13 may form a stacked structure 1.

The electrodes, for example, the gate electrode 21, the source electrode 22, and the drain electrode 23, may be in contact with the nitride semiconductor layer 13. In some embodiments, the electrodes, for example, the gate electrode 21, the source electrode 22, and the drain electrode 23, may be disposed on the nitride semiconductor layer 13. The gate electrode 21 may be disposed between the source electrode 22 and the drain electrode 23. The gate electrode 21 may include a metal. In some embodiments, the gate electrode 21 may include titanium (Ti), tantalum (Ta), tungsten (W), aluminum (Al), cobalt (Co), copper (Cu), nickel (Ni), platinum (Pt), lead (Pb), molybdenum (Mo), and compounds thereof, for example, but not limited to, titanium nitride (TiN), tantalum nitride (TaN), other conductive nitrides or conductive oxides, metal alloys, for example, aluminum-copper alloy (Al—Cu), or other suitable material. The source electrode 22 may include, for example, but not limited to, a conductive material. In some embodiments, the conductive material may include metals, alloys, doped semiconductive materials (e.g., doped crystalline silicon), or other suitable conductive materials, for example, Ti, Al, Ni, Cu, Au, Pt, Pd, W, TiN, or other suitable materials. The drain electrode 23 may include, for example, but not limited to, a conductive material. The conductive material may include metals, alloys, doped semiconductive materials (e.g., doped crystalline silicon), or other suitable conductive materials, for example, Ti, Al, Ni, Cu, Au, Pt, Pd, W, TiN, or other suitable materials. In some embodiments, the drain electrode 23 may have a structure similar to or the same as that of the source electrode 22.

The dielectric structure 30 may be disposed on the nitride semiconductor layer 13. In some embodiments, the dielectric structure 30 may include a plurality of dielectric layers including, for example, a dielectric layer 31, a dielectric layer 32, and a dielectric layer 33. The dielectric structure 30, for example, the dielectric layer 31, may cover the electrodes, including, for example, the gate electrode 21, the source electrode 22, and the drain electrode 23. The dielectric layers, for example, the dielectric layer 31, the dielectric layer 32, and the dielectric layer 33, may be stacked on top of each other. For example, the dielectric layer 31 may be disposed on the nitride semiconductor layer 13, the dielectric layer 32 may be disposed on the dielectric layer 31, and the dielectric layer 33 may be disposed on the dielectric layer 32. In some embodiments, a thickness t₃ of the dielectric layer 33 may be greater than a thickness t₁ of the dielectric layer 31 and a thickness t₂ of the dielectric layer 32. For example, the thickness t₃ of the dielectric layer 33 may be two or three times the thickness t₁ of the dielectric layer 31, or may be two or three times the thickness t₂ of the dielectric layer 32. In some embodiments, as shown in FIG. 1, the dielectric structure 30 may define an opening 35, an opening 36, and an opening 37. The opening 35 penetrates through the dielectric layer 32. The opening 36 penetrates through the dielectric layer 32 and the dielectric layer 31. The opening 37 penetrates through the dielectric layer 33.

In some embodiments, the dielectric structure 30, including, for example, the dielectric layer 31, the dielectric layer 32, and the dielectric layer 33, may include a high dielectric constant (high-κ) material. The high dielectric constant material may have a k value greater than about 5. In some embodiments, the dielectric structure 30, including, for example, the dielectric layer 31, the dielectric layer 32, and the dielectric layer 33 may include a low dielectric constant (low-κ) material. The low dielectric constant material may have a k value less than about 5. In some embodiments, the dielectric structure 30, including, for example, the dielectric layer 31, the dielectric layer 32, and the dielectric layer 33 may include oxides, nitrides, nitrogen oxides, or other suitable materials. In some embodiments, the dielectric layer 31, the dielectric layer 32, and the dielectric layer 33 may include the same material. In some embodiments, the dielectric layer 31, the dielectric layer 32, and the dielectric layer 33 may include partially the same material. In some embodiments, the dielectric layer 31, the dielectric layer 32, and the dielectric layer 33 may include different materials. In some embodiments, there may be incomplete boundaries between adjacent dielectric layers, e.g., between the dielectric layer 31 and the dielectric layer 32, and between the dielectric layer 32 and the dielectric layer 33, for example, a part of an interface has boundaries that may be identified by a scanning electron microscope (SEM), and another part of the interface has no boundaries that may be observed by the SEM. In some embodiments, there may be substantially no boundaries between adjacent dielectric layers, e.g., between the dielectric layer 31 and the dielectric layer 32, and between the dielectric layer 32 and the dielectric layer 33.

The field plate 25 may be located in the dielectric structure 30. In some embodiments, as shown in FIG. 1, the field plate 25 may be disposed on the dielectric layer 31. The dielectric layer 32 may cover the field plate 25. The field plate 25 may be adjacent to and spaced apart from the gate electrode 21. The field plate 25 may include a conductive material. In some embodiments, the conductive material may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo), and compounds thereof, for example, but not limited to, titanium nitride (TiN), tantalum nitride (TaN), other conductive nitrides or conductive oxides, metal alloys, for example, aluminum-copper alloy (Al—Cu), or other suitable materials. A thickness of the field plate 25 may range, but is not limited to, from about 50 nm to about 300 nm. In some embodiments, the field plate 25 may be at zero potential.

The height compensators, for example, the height compensator 412, the height compensator 422, the height compensator 432, and the height compensator 442, may be located in the dielectric structure 30. The height compensators, for example, the height compensator 412, the height compensator 422, the height compensator 432, and the height compensator 442, may be in contact with the dielectric layer 33. In some embodiments, the height compensator, e.g., the height compensator 422 may be located in the opening 35 and disposed on the field plate 25, such that the height compensator, e.g., the height compensator 422 may penetrate through the dielectric layer 32. In some embodiments, the height compensators, for example, the height compensator 412, the height compensator 432, and the height compensator 442, may be located in openings 36 and disposed on the electrodes, for example, the gate electrode 21, the source electrode 22, and the drain electrode 23, such that the height compensators, for example, the height compensator 412, the height compensator 432, and the height compensator 442, may penetrate through the dielectric layer 32 and the dielectric layer 31. In some embodiments, top surfaces of the height compensators, including, for example, a top surface 410 of the height compensator 412, a top surface 420 of the height compensator 422, a top surface 430 of the height compensator 432, and a top surface 440 of the height compensator 442, may be coplanar with each other.

In some embodiments, as shown in FIG. 1, the height compensators, e.g., the height compensator 412, the height compensator 422, the height compensator 432, and the height compensator 442, may include lower via portions, e.g., a lower via portion 413 of the height compensator 412, a lower via portion 423 of the height compensator 422, a lower via portion 433 of the height compensator 432, and a lower via portion 443 of the height compensator 442, and upper connecting portions, e.g., an upper connecting portion 414 of the height compensator 412, an upper connecting portion 424 of the height compensator 422, an upper connecting portion 434 of the height compensator 432, and an upper connecting portion 444 of the height compensator 442. The upper connecting portions, e.g., the upper connecting portion 414 of the height compensator 412, the upper connecting portion 424 of the height compensator 422, the upper connecting portion 434 of the height compensator 432, and the upper connecting portion 444 of the height compensator 442, may be on a top surface of the dielectric layer 32 and above the lower via portions, e.g., the lower via portion 413 of the height compensator 412, the lower via portion 423 of the height compensator 422, the lower via portion 433 of the height compensator 432, and the lower via portion 443 of the height compensator 442. In some embodiments, widths of the upper connecting portions, e.g., the upper connecting portion 414, the upper connecting portion 424, the upper connecting portion 434, and the upper connecting portion 444, may be respectively greater than widths of the lower via portions, e.g., the lower via portion 413, the lower via portion 423, the lower via portion 433, and the lower via portion 443. For example, the width w₃₁ of the upper connecting portion 414 of the height compensator 412 may be greater than the width w₂₁ of the lower via portion 413 of the height compensator 412, the width w₃₂ of the upper connecting portion 424 of the height compensator 422 may be greater than the width w₂₂ of the lower via portion 423 of the height compensator 422, the width w₃₃ of the upper connecting portion 434 of the height compensator 432 may be greater than the width w₂₃ of the lower via portion 433 of the height compensator 432, and the width w₃₄ of the upper connecting portion 444 of the height compensator 442 may be greater than the width w₂₄ of the lower via portion 443 of the height compensator 442. In some embodiments, the lower via portion 413 and the upper connecting portion 414 of the height compensator 412 may be integrally formed into a monolithic structure, the lower via portion 423 and the upper connecting portion 424 of the height compensator 422 may be integrally formed into a monolithic structure, the lower via portion 433 and the upper connecting portion 434 of the height compensator 432 may be integrally formed into a monolithic structure, and the lower via portion 443 and the upper connecting portion 444 of the height compensator 442 may be integrally formed into a monolithic structure. In some embodiments, the upper connecting portions (e.g., the upper connecting portion 424 of the height compensator 422) may be of a field plate structure.

In some embodiments, heights of the height compensators, e.g., a height h₁ of the height compensator 412, a height h₂ of the height compensator 422, and a height h₃ of the height compensator 432 or a height h₄ of the height compensator 442 may be different from each other, to compensate for a height difference (or step difference) between the electrodes (e.g., the gate electrode 21, the source electrode 22, and the drain electrode 23) and the field plate 25. In some embodiments, the height compensators, including, for example, the height compensator 412, the height compensator 422, the height compensator 432, and the height compensator 442 may include the same material as that of the field plate 25. The height compensators, for example, the height compensator 412, the height compensator 422, the height compensator 432, and the height compensator 442, may include conductive materials. The materials of the height compensators, for example, the height compensator 412, the height compensator 422, the height compensator 432, and the height compensator 442, may include, for example, but not limited to, titanium (Ti), tantalum (Ta), tungsten (W), aluminum (Al), cobalt (Co), copper (Cu), nickel (Ni), platinum (Pt), lead (Pb), molybdenum (Mo), and compounds thereof, for example, but not limited to, titanium nitride (TiN), tantalum nitride (TaN), other conductive nitrides or conductive oxides, metal alloys, for example, aluminum-copper alloy (Al—Cu), or other suitable materials.

The vias, e.g., the via 411, the via 421, the via 431, and the via 441, may extend from a top surface of the dielectric structure 30, i.e., a top surface of the dielectric layer 33, into the dielectric structure 30. In some embodiments, the vias, e.g., the via 411, the via 421, the via 431, and the via 441, may be located in openings 37 and disposed on top surfaces of the height compensators, e.g., the top surface 410 of the height compensator 412, the top surface 420 of the height compensator 422, the top surface 430 of the height compensator 432, and the top surface 440 of the height compensator 442. Accordingly, the vias, e.g., the via 411, the via 421, the via 431, and the via 441, may penetrate through the dielectric layer 33 and respectively contact the top surfaces of the height compensators, e.g., the top surface 410 of the height compensator 412, the top surface 420 of the height compensator 422, the top surface 430 of the height compensator 432, and the top surface 440 of the height compensator 442. Moreover, since the top surfaces of the height compensators, including, for example, the top surface 410 of the height compensator 412, the top surface 420 of the height compensator 422, the top surface 430 of the height compensator 432, and the top surface 440 of the height compensator 442, are coplanar with each other, lengths of the vias, including, for example, a length L₁ of the via 411, a length L₂ of the via 421, a length L₃ of the via 431, and a length La of the via 441, may be the same as each other. Bottom surfaces of the vias, including, for example, a bottom surface of the via 411, a bottom surface of the via 421, a bottom surface of the via 431, and a bottom surface of the via 441 may be coplanar with each other, that is, the bottom surfaces of all the vias, including, for example, the bottom surface of the via 411, the bottom surface of the via 421, the bottom surface of the via 431, and the bottom surface of the via 441 are at the same height. In some embodiments, as shown in FIG. 1, the vias, e.g., the via 411, the via 421, the via 431, and the via 441, may respectively form non-linear via structures with the contacted height compensators, e.g., the height compensator 412, the height compensator 422, the height compensator 432, and the height compensator 442. Therefore, the vias, including, for example, the via 411, the via 421, the via 431, and the via 441, may also be referred to as via portions, including, for example, the via portion 411, the via portion 421, the via portion 431, and the via portion 441. The height compensators, including, for example, the height compensator 412, the height compensator 422, the height compensator 432, and the height compensator 442, may also be referred to as height-compensation portions, including, for example, the height-compensation portion 412, the height-compensation portion 422, the height-compensation portion 432, and the height-compensation portion 442. The height-compensation portions, e.g., the height-compensation portion 412, the height-compensation portion 422, the height-compensation portion 432, and the height-compensation portion 442, may be located below the via portions, e.g., the via portion 411, the via portion 421, the via portion 431, and the via portion 441.

In some embodiments, the vias, e.g., the via 411, the via 421, the via 431, and the via 441 may respectively contact the upper connecting portions of the height compensators, e.g., the upper connecting portion 414 of the height compensator 412, the upper connecting portion 424 of the height compensator 422, the upper connecting portion 434 of the height compensator 432, and the upper connecting portion 444 of the height compensator 442. Moreover, the vias, e.g., the via 411, the via 421, the via 431, and the via 441, may be in misalignment with the lower via portions of the height compensators, e.g., the lower via portion 413 of the height compensator 412, the lower via portion 423 of the height compensator 422, the lower via portion 433 of the height compensator 432, and the lower via portion 443 of the height compensator 442. In some embodiments, the “misalignment” may include shifting or deviating of a geometric center of the via (e.g., a geometric center of the via 411, a geometric center of the via 421, a geometric center of the via 431, and a geometric center of the via 441) from a geometric center of the lower via portion of the height compensator (e.g., a geometric center of the lower via portion 413 of the height compensator 412, a geometric center of the lower via portion 423 of the height compensator 422, a geometric center of the lower via portion 433 of the height compensator 432, and a geometric center of the lower via portion 443 of the height compensator 442).

In some embodiments, as shown in FIG. 1, the lengths of the vias, e.g., the length L₁ of the via 411, the length L₂ of the via 421, the length L₃ of the via 431, and the length L₄ of the via 441, may be greater than the heights of the height compensators, e.g., the height h₁ of the height compensator 412, the height h₂ of the height compensator 422, and the height h₃ of the height compensator 432 or the height h₄ of the height compensator 442. In some embodiments, the widths of the upper connecting portions of the height compensators, for example, the width w₃₁ of the upper connecting portion 414 of the height compensator 412, the width w₃₂ of the upper connecting portion 424 of the height compensator 422, the width w₃₃ of the upper connecting portion 434 of the height compensator 432, and the width w₃₄ of the upper connecting portion 444 of the height compensator 442, may be respectively greater than widths of the vias, for example, a width w₁₁ of the via 411, a width w₁₂ of the via 421, a width w₁₃ of the via 431, and a width w₁₄ of the via 441, and the widths of the lower via portions of the height compensators, for example, the width w₂₁ of the lower via portion 413 of the height compensator 412, the width w₂₂ of the lower via portion 423 of the height compensator 422, the width w₂₃ of the lower via portion 433 of the height compensator 432, and the width w₂₄ of the lower via portion 443 of the height compensator 442, may be respectively greater than the widths of the vias, for example, the width w₁₁ of the via 411, the width w₁₂ of the via 421, the width w₁₃ of the via 431, and the width w₁₄ of the via 441. In some embodiments, geometries of the vias (e.g., the via 411, the via 421, the via 431, and the via 441) may be different from those of the height compensators (e.g., the height compensator 412, the height compensator 422, the height compensator 432, and the height compensator 442). The vias (e.g., the via 411, the via 421, the via 431, and the via 441) may include different materials from the height compensators (e.g., the height compensator 412, the height compensator 422, the height compensator 432, and the height compensator 442). In some embodiments, the materials of the vias (e.g., the via 411, the via 421, the via 431, and the via 441) may include, for example, but not limited to, titanium (Ti), tantalum (Ta), tungsten (W), aluminum (Al), cobalt (Co), copper (Cu), nickel (Ni), platinum (Pt), lead (Pb), molybdenum (Mo), and compounds thereof, for example, but not limited to, titanium nitride (TiN), tantalum nitride (TaN), other conductive nitrides or conductive oxides, metal alloys, for example, aluminium copper alloy (Al—Cu), or other suitable materials.

In a semiconductor apparatus according to a comparative example, no height compensators are provided. In such a case, vias with different lengths are required to contact electrodes and field plate with different heights. Under-etching (for example, etching that does not reach a stop layer) or etching-through (for example, etching through the stop layer) is prone to occur during formation of the vias with different lengths by an etching process. In embodiments of the present disclosure, height compensators (including, for example, the height compensator 412, the height compensator 422, the height compensator 432, and the height compensator 442) compensate for the height difference (or step difference) between the electrodes (e.g., the gate electrode 21, the source electrode 22, and the drain electrode 23) and the field plate 25, such that all vias (including, for example, the via 411, the via 421, the via 431, and the via 441) may be in contact with the height compensators (including, for example, the height compensator 412, the height compensator 422, the height compensator 432, and the height compensator 442) at the same height, and electrically connected to the electrodes (e.g., the gate electrode 21, the source electrode 22, and the drain electrode 23) and the field plate 25 through the height compensators (e.g., the height compensator 412, the height compensator 422, the height compensator 432, and the height compensator 442). Moreover, since bottom surfaces of all the vias (including, for example, the bottom surface of the via 411, the bottom surface of the via 421, the bottom surface of the via 431, and the bottom surface of the via 441) are at the same height, under-etching or etching-through can be avoided during formation of the vias (for example, the via 411, the via 421, the via 431, and the via 441). In addition, the height compensators (for example, the height compensator 412, the height compensator 422, the height compensator 432, and the height compensator 442) may be provided to reduce the lengths of the vias (for example, the via 411, the via 421, the via 431, and the via 441), thereby saving the time required for the formation of the vias (for example, the via 411, the via 421, the via 431, and the via 441).

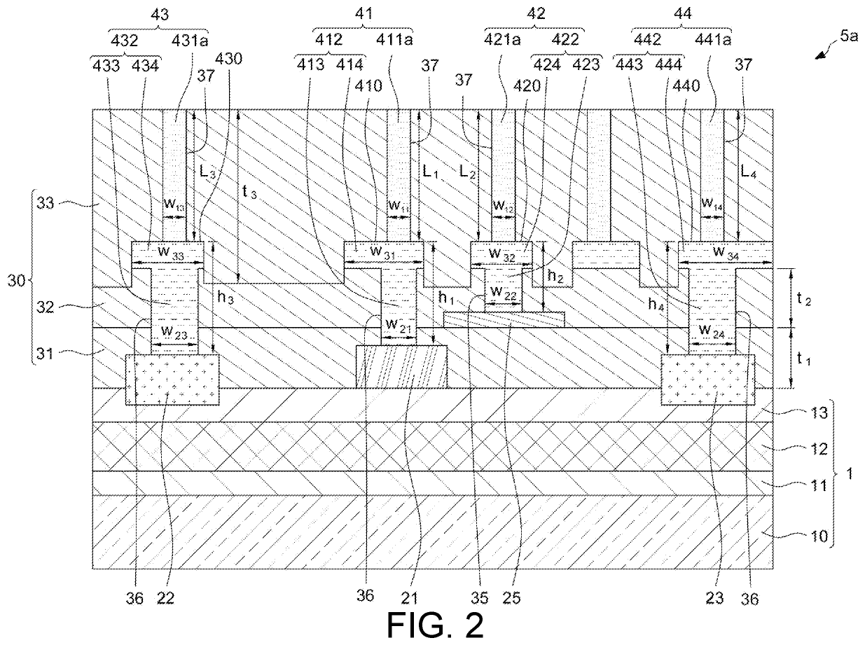

FIG. 2 shows a cross-sectional view of a semiconductor apparatus 5a according to some embodiments of the present disclosure. The semiconductor apparatus 5a in FIG. 2 has a similar structure to that of the semiconductor apparatus 5 in FIG. 1 except for the arrangement of vias (including, for example, a via 411a, a via 421a, a via 431a, and a via 441a) in the semiconductor apparatus 5a in FIG. 2. In some embodiments, as shown in FIG. 2, the vias, e.g., the via 411a, the via 421a, the via 431a, and the via 441a, may be in alignment with the lower via portions of the height compensators, e.g., the lower via portion 413 of the height compensator 412, the lower via portion 423 of the height compensator 422, the lower via portion 433 of the height compensator 432, and the lower via portion 443 of the height compensator 442, in consideration of circuit designs. In some embodiments, the “alignment” may include aligning of a geometric center of the via (e.g., a geometric center of the via 411a, a geometric center of the via 421a, a geometric center of the via 431a, and a geometric center of the via 441a) with the geometric center of the lower via portion of the height compensator (e.g., the geometric center of the lower via portion 413 of the height compensator 412, the geometric center of the lower via portion 423 of the height compensator 422, the geometric center of the lower via portion 433 of the height compensator 432, and the geometric center of the lower via portion 443 of the height compensator 442).

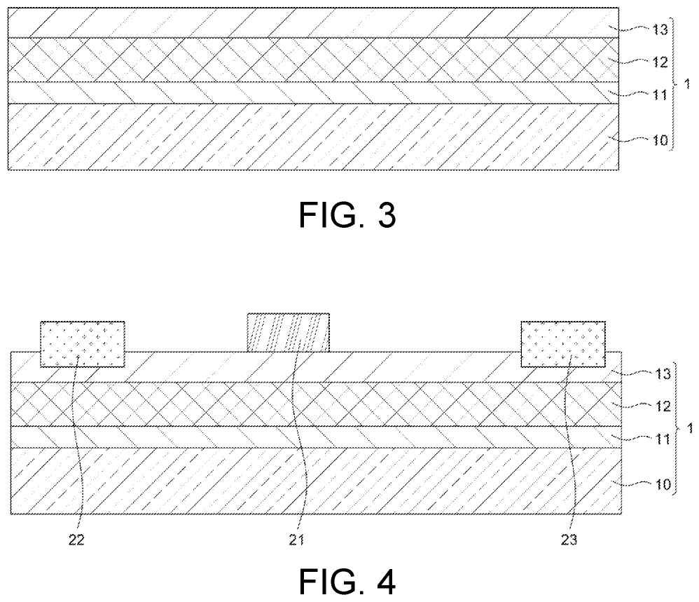

FIG. 3 to FIG. 15 show one or more stages of a method of manufacturing a semiconductor apparatus according to some embodiments of the present disclosure. In some embodiments, the method is used to manufacture the semiconductor apparatus 5 as shown in FIG. 1.

Referring to FIG. 3, a stacked structure 1 is provided. The stacked structure 1 may include a base substrate 10, a buffer layer 11, a nitride semiconductor layer 12, and a nitride semiconductor layer 13. The base substrate 10 in FIG. 3 may be the same as the base substrate 10 in FIG. 1. The buffer layer 11 in FIG. 3 may be the same as the buffer layer 11 in FIG. 1. The nitride semiconductor layer 12 in FIG. 3 may be the same as the nitride semiconductor layer 12 in FIG. 1. The nitride semiconductor layer 13 in FIG. 3 may be the same as the nitride semiconductor layer 13 in FIG. 1. Therefore, as shown in FIG. 3, the buffer layer 11 may be formed on the base substrate 10, the nitride semiconductor layer 12 may be formed on the buffer layer 11, and the nitride semiconductor layer 13 may be formed on the nitride semiconductor layer 12.

Referring to FIG. 4, electrodes, including, for example, a gate electrode 21, a source electrode 22, and a drain electrode 23 are formed on the nitride semiconductor layer 13 by, for example, a deposition process (e.g., a physical vapor deposition process, a chemical vapor deposition process, or an atomic layer deposition process) or an electroplating process. The electrodes in FIG. 4, including, for example, the gate electrode 21, the source electrode 22, and the drain electrode 23 may be the same as the electrodes in FIG. 1, including, for example, the gate electrode 21, the source electrode 22, and the drain electrode 23.

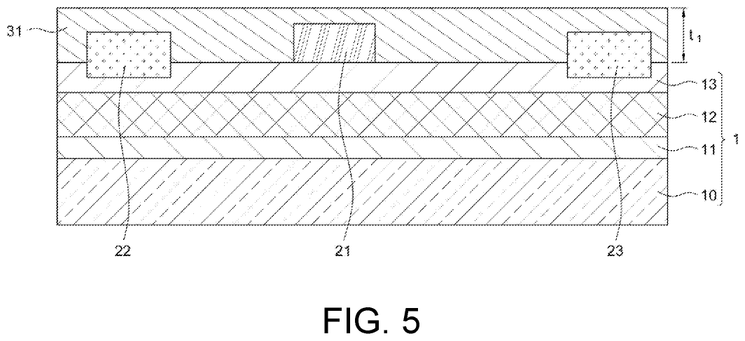

Referring to FIG. 5, a dielectric layer 31 is formed on the nitride semiconductor layer 13 by, for example, a deposition process, a coating process, or a sputtering process to cover the electrodes, including, for example, the gate electrode 21, the source electrode 22, and the drain electrode 23. The dielectric layer 31 in FIG. 5 may be the same as the dielectric layer 31 in FIG. 1.

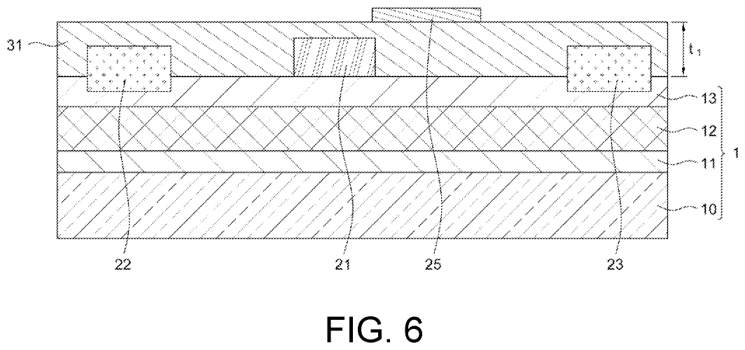

Referring to FIG. 6, a field plate 25 is formed on the dielectric layer 31 by, for example, a deposition process (e.g., a physical vapor deposition process, a chemical vapor deposition process, or an atomic layer deposition process), an electroplating process, or a sputtering process in combination with a patterning process. In some embodiments, the patterning process may include defining a pattern for the field plate 25 with a dry etching process or a wet etching process. The field plate 25 in FIG. 6 may be the same as the field plate 25 in FIG. 1.

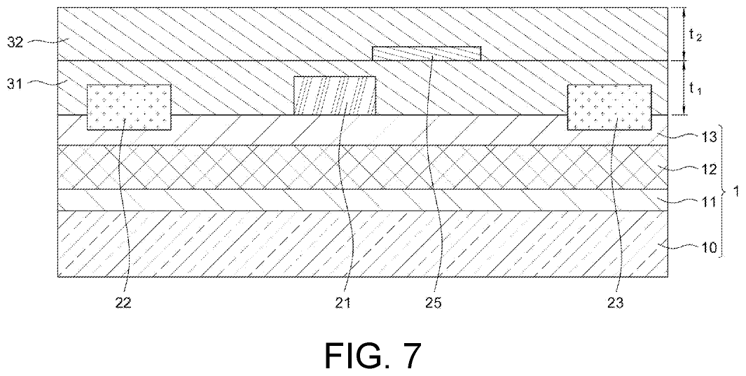

Referring to FIG. 7, a dielectric layer 32 is formed on the dielectric layer 31 by, for example, a deposition process, a coating process, or a sputtering process to cover the field plate 25. The dielectric layer 32 in FIG. 7 may be the same as the dielectric layer 32 in FIG. 1.

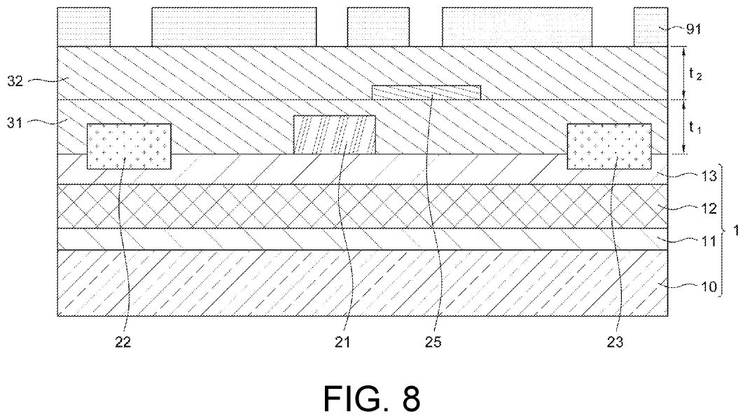

Referring to FIG. 8, a patterned hard mask 91 is formed on the dielectric layer 32.

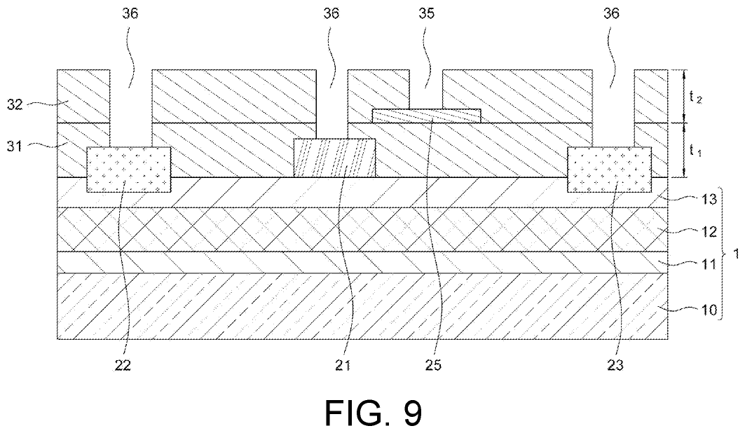

Referring to FIG. 8 and FIG. 9, an opening 35 penetrating through the dielectric layer 32 and openings 36 penetrating through the dielectric layer 32 and the dielectric layer 31 are formed by, for example, an etching process (e.g., a dry etching process) and the patterned hard mask 91, to expose a portion of the field plate 25 and a portion of the electrodes (including, for example, a portion of the gate electrode 21, a portion of the source electrode 22, and a portion of the drain electrode 23), respectively. Thereafter, the patterned hard mask 91 is removed. In some embodiments, as shown in FIG. 9, a depth of the opening 36 is different from a depth of the opening 35.

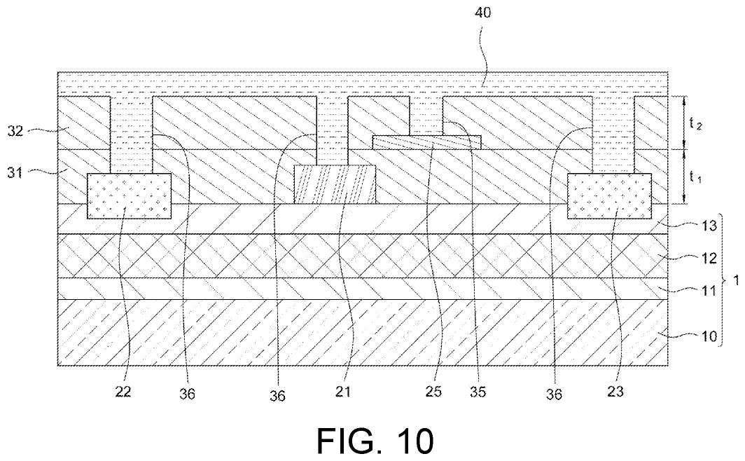

Referring to FIG. 10, a conductive material 40 is formed by, for example, a deposition process (e.g., a physical vapor deposition process, a chemical vapor deposition process, or an atomic layer deposition process), an electroplating process, or a sputtering process, on the dielectric layer 32, in the opening 35, on the exposed portion of the field plate 25, in the openings 36, and on the exposed portions of the electrodes (including, for example, the exposed portion of the gate electrode 21, the exposed portion of the source electrode 22, and the exposed portion of the drain electrode 23). The conductive material 40 may include, for example, but is not limited to, titanium (Ti), tantalum (Ta), tungsten (W), aluminum (Al), cobalt (Co), copper (Cu), nickel (Ni), platinum (Pt), lead (Pb), molybdenum (Mo), and compounds thereof, for example, but not limited to, titanium nitride (TiN), tantalum nitride (TaN), other conductive nitrides or conductive oxides, metal alloys, for example, aluminum-copper alloy (Al—Cu), or other suitable materials.

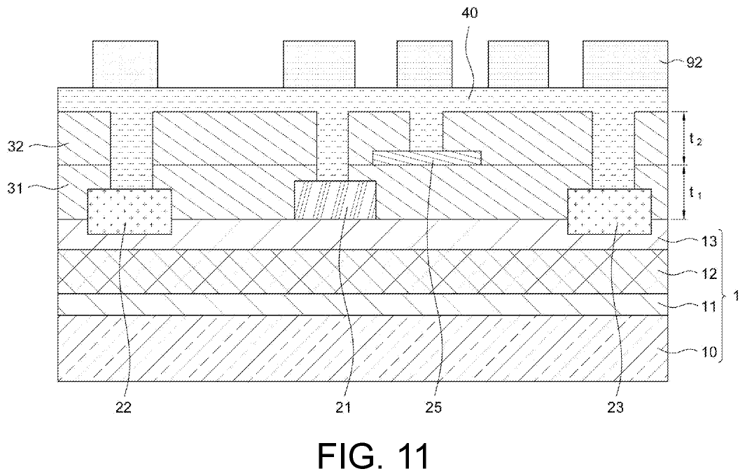

Referring to FIG. 11, a patterned hard mask 92 is formed on the conductive material 40.

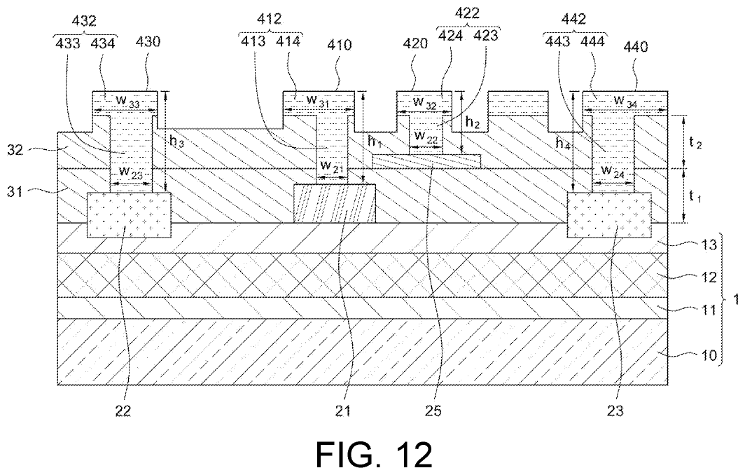

Referring to FIG. 11 and FIG. 12, the conductive material 40 is patterned by, for example, an etching process (e.g., a dry etching process) and the patterned hard mask 92, to form a plurality of height compensators (including, for example, a height compensator 412, a height compensator 422, a height compensator 432, and a height compensator 442) penetrating through the dielectric layer 32 and respectively contacting the electrodes (e.g., the gate electrode 21, the source electrode 22, and the drain electrode 23) and the field plate 25. Thereafter, the patterned hard mask 92 is removed. In some embodiments, as shown in FIG. 12, the height compensators, for example, the height compensator 412, the height compensator 432, and the height compensator 442, may further penetrate through the dielectric layer 31 to respectively contact the electrodes, for example, the gate electrode 21, the source electrode 22, and the drain electrode 23. The height compensators in FIG. 12, including, for example, the height compensator 412, the height compensator 422, the height compensator 432, and the height compensator 442 may be the same as the height compensators in FIG. 1, including, for example, the height compensator 412, the height compensator 422, the height compensator 432, and the height compensator 442. Accordingly, top surfaces of the height compensators in FIG. 12, including, for example, a top surface 410 of the height compensator 412, a top surface 420 of the height compensator 422, a top surface 430 of the height compensator 432, and a top surface 440 of the height compensator 442, may be coplanar with each other.

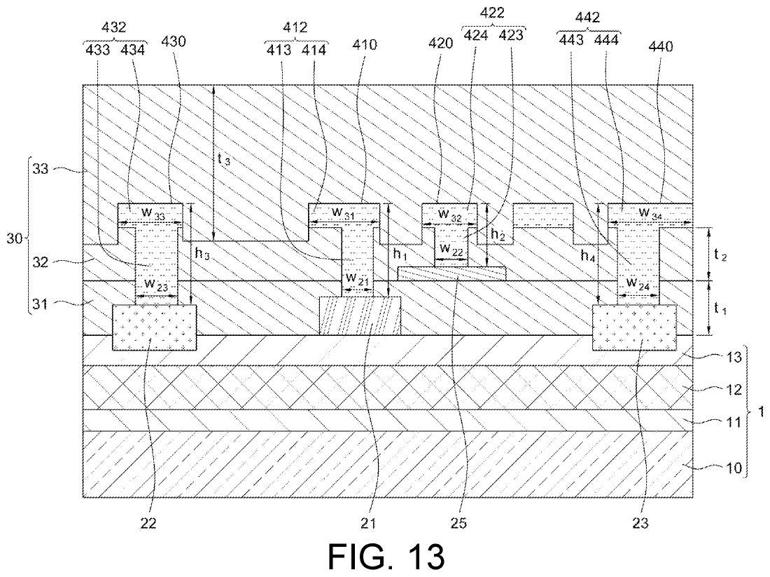

Referring to FIG. 13, a dielectric layer 33 is formed on the dielectric layer 32 by, for example, a deposition process, a coating process, or a sputtering process, to cover the height compensators (including, for example, the height compensator 412, the height compensator 422, the height compensator 432, and the height compensator 442). The dielectric layer 33 in FIG. 13 may be the same as the dielectric layer 33 in FIG. 1. Accordingly, a thickness t₃ of the dielectric layer 33 in FIG. 13 may be greater than a thickness t₁ of the dielectric layer 31 and a thickness t₂ of the dielectric layer 32. In addition, the dielectric layer 31, the dielectric layer 32, and the dielectric layer 33 in FIG. 13 may form a dielectric structure 30.

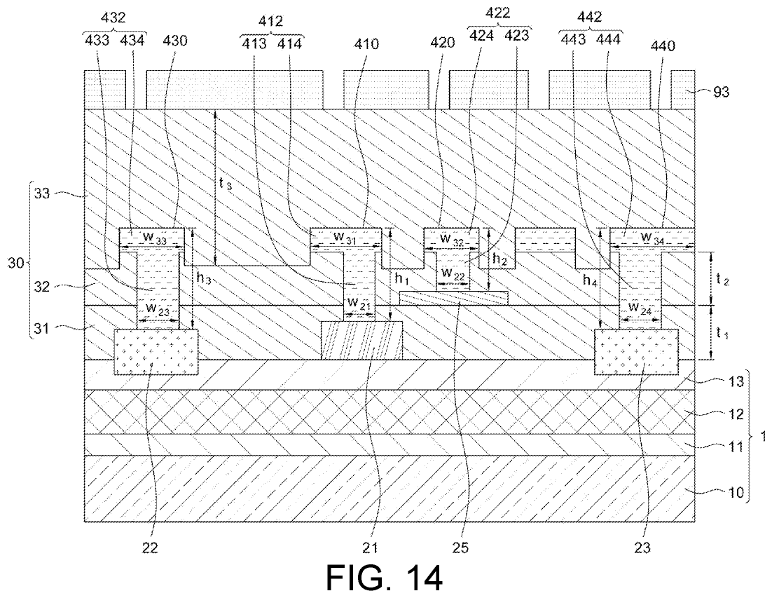

Referring to FIG. 14, a patterned hard mask 93 is formed on the dielectric layer 33.

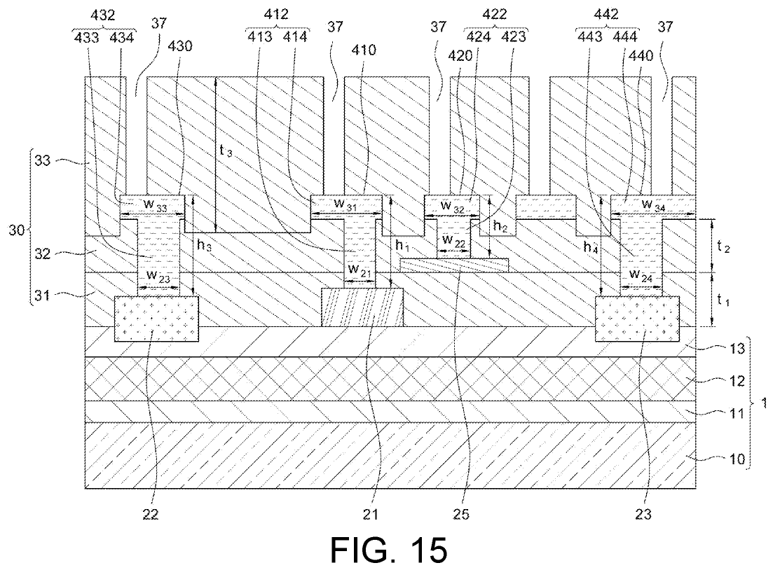

Referring to FIG. 14 and FIG. 15, openings 37 penetrating through the dielectric layer 33 are formed by, for example, an etching process (e.g., a dry etching process) and the patterned hard mask 93, to expose portions of the top surfaces of the height compensators, including, for example, a portion of the top surface 410 of the height compensator 412, a portion of the top surface 420 of the height compensator 422, a portion of the top surface 430 of the height compensator 432, and a portion of the top surface 440 of the height compensator 442. Since the top surfaces of the height compensators, including, for example, the top surface 410 of the height compensator 412, the top surface 420 of the height compensator 422, the top surface 430 of the height compensator 432, and the top surface 440 of the height compensator 442, are coplanar with each other, etching of the openings 37 may be stopped at the same height so as to avoid under-etching or etching-through during the formation of the openings 37. Thereafter, the patterned hard mask 93 is removed. In some embodiments, as shown in FIG. 15, all of the openings 37 are of the same depth.

Referring to FIG. 1, a plurality of vias (including, for example, a via 411, a via 421, a via 431, and a via 441) are formed by, for example, a deposition process (e.g., a physical vapor deposition process, a chemical vapor deposition process, or an atomic layer deposition process), an electroplating process, or a sputtering process, in the openings 37 and on the exposed portions of the top surfaces of the height compensators, including, for example, the exposed portion of the top surface 410 of the height compensator 412, the exposed portion of the top surface 420 of the height compensator 422, the exposed portion of the top surface 430 of the height compensator 432, and the exposed portion of the top surface 440 of the height compensator 442, to form the semiconductor apparatus 5 in FIG. 1.

As used herein, spatially relative terms, such as “beneath,” “below,” “lower,” “above,” “upper,” “lower,” “left,” “right” and the like, may be used herein for ease of description to describe one element or feature's relationship to another element(s) or feature(s) as illustrated in the figures. The spatially relative terms are intended to encompass different orientations of the apparatus in use or operation in addition to the orientation depicted in the figures. The apparatus may be otherwise oriented (rotated 80 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately”, “substantially”, “substantial” and “about” are used to describe and account for small variations. When used in conjunction with an event or circumstance, the terms can refer to instances in which the event or circumstance occurs precisely as well as instances in which the event or circumstance occurs to a close approximation. As used herein with respect to a given value or range, the term “about” generally refers to within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within +10%, +5%, +1%, or +0.5% of an average of the values.

The foregoing outlines features of several embodiments and detailed aspects of the present disclosure. The embodiments described in the present disclosure may be readily used as a basis for designing or modifying other processes and structures for carrying out the same or similar purposes and/or achieving the same or similar advantages of the embodiments introduced herein. Such equivalent constructions do not depart from the spirit and scope of the present disclosure, and various changes, substitutions, and alterations may be made without departing from the spirit and scope of the present disclosure.

1. A semiconductor apparatus, comprising:
a first nitride semiconductor layer;
a second nitride semiconductor layer on the first nitride semiconductor layer and having a bandgap greater than that of the first nitride semiconductor layer;
an electrode contacting the second nitride semiconductor layer;
a dielectric structure disposed on the second nitride semiconductor layer and covering the electrode;
a field plate in the dielectric structure;
a plurality of height compensators in the dielectric structure and disposed on the electrode and the field plate, respectively; and
a plurality of vias extending into the dielectric structure and contacting top surfaces of the plurality of height compensators, respectively.

2. The semiconductor apparatus of claim 1, wherein the top surfaces of the plurality of height compensators are coplanar.

3. The semiconductor apparatus of claim 1, wherein the plurality of vias have a same length.

4. The semiconductor apparatus of claim 1, wherein each of the plurality of height compensators comprises a lower via portion and an upper connecting portion above the lower via portion, and each of the plurality of vias contacts the upper connecting portion of a respective height compensator.

5. The semiconductor apparatus of claim 4, wherein each of the plurality of vias is in misalignment with the lower via portion of the respective height compensator.

6. The semiconductor apparatus of claim 4, wherein each of the plurality of vias is in alignment with the lower via portion of the respective height compensator.

7. The semiconductor apparatus of claim 4, wherein the upper connecting portion of each of the plurality of height compensators has a width greater than that of a respective via.

8. The semiconductor apparatus of claim 4, wherein the lower via portion of each of the plurality of height compensators has a width greater than that of a respective via.

9. The semiconductor apparatus of claim 4, wherein for each of the plurality of height compensators, the upper connecting portion has a width greater than that of the lower via portion.

10. The semiconductor apparatus of claim 4, wherein for each of the plurality of height compensators, the upper connecting portion is of a field plate structure.

11. The semiconductor apparatus of claim 1, wherein each of the plurality of vias has a length greater than a height of a respective height compensator.

12. The semiconductor apparatus of claim 1, wherein the height compensators have geometries different from those of the vias.

13. The semiconductor apparatus of claim 1, wherein the height compensators comprise a material different from that of the vias.

14. The semiconductor apparatus of claim 1, wherein the height compensators comprise a same material as that of the field plate.

15. The semiconductor apparatus of claim 1, wherein the plurality of height compensators have different heights.

16. The semiconductor apparatus of claim 1, wherein the dielectric structure comprises a first dielectric layer covering the electrode, a second dielectric layer disposed on the first dielectric layer, and a third dielectric layer disposed on the second dielectric layer, the height compensators contacting the third dielectric layer and penetrating through the second dielectric layer.

17. The semiconductor apparatus of claim 16, wherein the third dielectric layer has a thickness greater than that of the second dielectric layer.

18. A method of manufacturing a semiconductor apparatus, comprising:
providing a stacked structure comprising a first nitride semiconductor layer and a second nitride semiconductor layer formed on the first nitride semiconductor layer, the second nitride semiconductor layer having a bandgap greater than that of the first nitride semiconductor layer;
forming an electrode on the second nitride semiconductor layer;
forming a first dielectric layer to cover the electrode;
forming a field plate on the first dielectric layer;
forming a second dielectric layer to cover the field plate;
forming a plurality of height compensators penetrating through the second dielectric layer and contacting the electrode and the field plate, respectively; and
forming a plurality of vias on the plurality of height compensators.

19. The method of claim 18, wherein top surfaces of the plurality of height compensators are coplanar.

20. The method of claim 18, further comprising:
forming a third dielectric layer to cover the plurality of height compensators, wherein the plurality of vias penetrate through the third dielectric layer.

21. A semiconductor apparatus, comprising:
a first nitride semiconductor layer;
a second nitride semiconductor layer on the first nitride semiconductor layer and having a bandgap greater than that of the first nitride semiconductor layer;
a plurality of electrodes contacting the second nitride semiconductor layer;
a dielectric structure disposed on the second nitride semiconductor layer and covering the plurality of electrodes;
a field plate in the dielectric structure; and
a plurality of via structures extending into the dielectric structure and disposed on the plurality of electrodes, respectively, wherein each of the via structures comprises a via portion and a height-compensation portion disposed below the via portion.

22. The semiconductor apparatus of claim 21, wherein the plurality of via structures are disposed on the plurality of electrodes and the field plate, respectively, and a height of the height-compensation portion of the via structure disposed on the field plate is different from heights of the height-compensation portions of the via structures disposed on the electrodes.

23. The semiconductor apparatus of claim 21, wherein top surfaces of the height-compensation portions of the plurality of via structures are coplanar.
